(19) United States
(12) Patent Application Publication
(10) Pub. No.: US 2016/0248422 A1
(43) Pub. Date: Aug. 25, 2016

(54) SWITCHING CIRCUIT, SEMICONDUCTOR SWITCHING ARRANGEMENT AND METHOD

(71) Applicant: Infineon Technologies Austria AG, Villach (AT)

(72) Inventors: Gilberto Curatola, Villach (AT); Oliver Haeberlen, Villach (AT); Ralf Siemieniec, Villach (AT)

(21) Appl. No.: 14/629,551

(22) Filed: Feb. 24, 2015

(51) Int. Cl. H03K 17/687; H03K 17/04

(52) U.S. Cl. CPC H03K 17/6871; H03K 17/04

(57) ABSTRACT

In an embodiment, a switching circuit includes a high voltage depletion mode transistor having a first leakage current and operatively connected in a cascode arrangement to a low voltage enhancement mode transistor having a second leakage current. The second leakage current is larger than the first leakage current.

### BACKGROUND

To date, transistors used in power electronic applications have typically been fabricated with silicon (Si) semiconductor materials. Common transistor devices for power applications include Si CoolMOS®, Si Power MOSFETs, and Si Insulated Gate Bipolar Transistors (IGBTs). More recently, silicon carbide (SiC) power devices have been considered. Group III-N semiconductor devices, such as gallium nitride (GaN) devices, are now emerging as attractive candidates to carry large currents, support high voltages and to provide very low on-resistance and fast switching times.

### SUMMARY

In an embodiment, a switching circuit includes a high voltage depletion mode transistor having a first leakage current operatively connected in a cascode arrangement to a low voltage enhancement mode transistor having a second leakage current, the second leakage current being larger than the first leakage current.

In an embodiment, a method includes adjusting the leakage current of a low voltage enhancement mode transistor in a switching circuit comprising a high voltage depletion mode transistor operatively connected in a cascode arrangement to the low voltage enhancement mode transistor such that the leakage current of the low voltage enhancement mode transistor is higher than the leakage current of the high voltage depletion mode transistor within a predetermined temperature range.

In an embodiment, a semiconductor switching arrangement includes a normally-on semiconductor component having a first current electrode, a second current electrode and a first control electrode, the normally-on semiconductor component providing a first leakage current, a normally-off semiconductor component having a third current electrode, a fourth current electrode and a second control electrode, the third current electrode being coupled to the first control electrode and to a reference terminal and the fourth current electrode being coupled to the first current electrode, the normally-off semiconductor component providing a second leakage current and an actuation circuit having a fifth current electrode and a sixth current electrode, the sixth current electrode being coupled to the reference terminal and the fifth current electrode being coupled to the second control electrode to provide a control signal for switching the normally-off semiconductor component on or off. The second leakage current is larger than the first leakage current.

In an embodiment, a semiconductor switching arrangement includes a normally-on semiconductor component having a first current electrode, a second current electrode and a first control electrode, a normally-off semiconductor component having a third current electrode, a fourth current electrode and a second control electrode, the third current electrode being coupled to the first control electrode and to a reference terminal and the fourth current electrode being coupled to the first current electrode and an actuation circuit having a fifth current electrode and a sixth current electrode, the sixth current electrode being coupled to the reference terminal and the fifth current electrode being coupled to the second control electrode to provide a control signal for switching the normally-off semiconductor component on or off. An output capacitance of the normally-on semiconductor component and an output capacitance of the normally-off semiconductor component fulfill the condition (COSS_Non*V_DD)/(COSS_Noff+CGS_Non)<Vbr_Noff−Vth_Non, wherein COSS_Non denotes the output capacitance of the normally-on semiconductor component, COSS_Noff denotes the output capacitance of the normally-off semiconductor component, CGS_Non denotes the capacitance between the first control electrode and the first current electrode, V_DD denotes the supply voltage, Vbr_Noff denotes the break-down voltage of the normally-off semiconductor component and Vth_Non denotes the threshold voltage of the normally-on semiconductor component.

Those skilled in the art will recognize additional features and advantages upon reading the following detailed description, and upon viewing the accompanying drawings.

### BRIEF DESCRIPTION OF THE DRAWINGS

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a schematic circuit diagram of a semiconductor switching arrangement according to a first embodiment.

FIG. 2 illustrates a schematic circuit diagram of a semiconductor switching arrangement according to a second embodiment.

FIG. 3 illustrates a schematic circuit diagram of a semiconductor switching arrangement according to a third embodiment.

FIG. 4 illustrates a schematic circuit diagram of a semiconductor switching arrangement according to a fourth embodiment.

FIG. 5 illustrates a schematic circuit diagram of a semiconductor switching arrangement according to a fifth embodiment.

### DETAILED DESCRIPTION

In the following detailed description, reference is made to the accompanying drawings, which form a part hereof, and in which is shown by way of illustration specific embodiments in which the invention may be practiced. In this regard, directional terminology, such as “top”, “bottom”, “front”, “back”, “leading”, “trailing”, etc., is used with reference to the orientation of the figure(s) being described. Because components of the embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, thereof, is not to be taken in a limiting sense, and the scope of the present invention is defined by the appended claims.

A number of embodiments will be explained below. In this case, identical structural features are identified by identical or similar reference symbols in the figures. In the context of the present description, “lateral” or “lateral direction” should be understood to mean a direction or extent that runs generally parallel to the lateral extent of a semiconductor material or semiconductor carrier. The lateral direction thus extends generally parallel to these surfaces or sides. In contrast thereto, the term “vertical” or “vertical direction” is understood to mean a direction that runs generally perpendicular to these surfaces or sides and thus to the lateral direction. The vertical direction therefore runs in the thickness direction of the semiconductor material or semiconductor carrier.

As employed in this specification, the terms “coupled” and/or “electrically coupled” are not meant to mean that the elements must be directly coupled together-intervening elements may be provided between the “coupled” or “electrically coupled” elements.

A depletion-mode device, such as a high-voltage depletion-mode transistor, has a negative threshold voltage which means that it can conduct current at zero gate voltage. These devices are normally on. An enhancement-mode device, such as a low-voltage enhancement-mode transistor, has a positive threshold voltage which means that it cannot conduct current at zero gate voltage and is normally off.

As used herein, the phrase “Group III nitride” refers to a compound semiconductor that includes nitrogen (N) and at least one Group III element, including aluminum (Al), gallium (Ga), indium (In), and boron (B), and including but not limited to any of its alloys, such as aluminum gallium nitride (AlₓGa₍₁₋ₓ₎N), indium gallium nitride (In_{y}Ga_{(1-y)}N), aluminum indium gallium nitride (AlₓIn_{y}Ga_{(1-x-y)}N), gallium arsenide phosphide nitride (GaAsₐP_{b}N_{(1-a-b)}) and aluminum indium gallium arsenide phosphide nitride (AlₓIn_{y}Ga_{(1-x-y)}; AsₐPbN_{(1-a-b)}), for example. Aluminum gallium nitride refers to an alloy described by the formula AlₓGa₍₁₋ₓ₎N, where x<1.

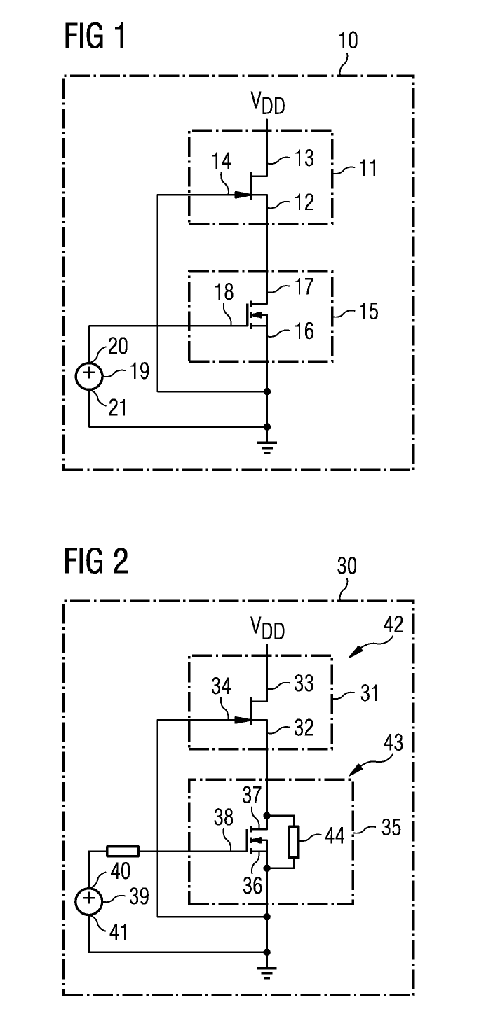

FIG. 1 illustrates a schematic circuit diagram of a semiconductor switching arrangement 10 according to a first embodiment.

The semiconductor switching arrangement 10 includes a normally-on semiconductor component 11, such as a depletion mode transistor, which has a first current electrode 12, a second current electrode 13 and a first control electrode 14. The normally-on semiconductor component 11 has a first leakage current. The semiconductor switching arrangement 10 further includes a normally-off semiconductor component 15, such as an enhancement mode transistor, which has a third current electrode 16, a fourth current electrode 17 and a second control electrode 18. The third current electrode 16 is connected to the first control electrode 14 and the fourth current electrode 17 is connected to the first current electrode 12. The normally-off semiconductor component 15 has a second leakage current. The semiconductor switching arrangement further includes an actuation circuit 19 electrically coupled to the second control electrode 18 which is configured to switch the normally-off semiconductor component 15 on or off. In particular, the actuation circuit 19 has a fifth current electrode 20 and a sixth current electrode 21.The sixth current electrode 21 is connected to a reference terminal and the fifth current electrode 20 is connected to the second control electrode 18. The second leakage current is larger than the first leakage current.

The normally-on semiconductor component may include a wide band gap semiconductor material such as silicon carbide or a group II nitride such as gallium nitride or aluminium gallium nitride.

The normally-off semiconductor component may include a second semiconductor material which is different to the semiconductor material or class of semiconductor materials used to form the normally-on semiconductor component. The second semiconductor material may include silicon.

The normally-on semiconductor component can be a High Electron Mobility Transistor (HEMT) or a Junction Field Effect Transistor (JFET). The normally-off semiconductor component can be a transistor device such as a MOSFET.

The second leakage current may be ten times larger than the first leakage current.

The sixth current electrode 21 and the third current electrode 16 are illustrated in FIG. 1 as being coupled to ground. However, the sixth current electrode 21 and the third current electrode 16 may be coupled to a reference terminal and a reference potential which is higher than 0V.

The reference terminal may be coupled to ground, for example in a low-side switch or a higher potential, in for example a high-side switch.

The semiconductor switching arrangement may further include a resistor or a MOS-gated diode or a Schottky diode connected in parallel to the third current electrode and the fourth current electrode in order to adjust the leakage current of the normally-off semiconductor component.

A MOSFET includes an inherent bipolar body diode and may be used alone without an additional MOS-gated diode or Schottky diode coupled in parallel with the transistor device. In some embodiments, the diode barrier within the MOSFET may be reduced by including SiGe or SiGeC in the body zone. The use of SiGe or SiGeC in the body zone may lead to a decrease in the forward voltage VF and an increase in the leakage current without requiring any area of the MOSFET device.

An output capacitance of the normally-on semiconductor component and an output capacitance of the normally-off semiconductor component may fulfill the condition (C_{OSS}_{_}_{Non}*V_DD)/(C_{OSS}_{_}_{Noff}+C_{GS}_{_}_{Non})<Vbr_{—Noff}−Vth_{—Non}, wherein C_{OSS}_{_}_{Non} denotes the output capacitance of the normally-on semiconductor component, C _{OSS}_{_}_{Noff} denotes the output capacitance of the normally-off semiconductor component, C_{GS}_{_}_{Non} denotes the capacitance between the first control electrode and the first current electrode, V_DD denotes the supply voltage, Vbr_{—Noff} denotes the breakdown voltage of the normally-off semiconductor component and Vth_{—Non} denotes the threshold voltage of the normally-on semiconductor component.

For a high voltage normally-on semiconductor device, such as a high voltage depletion mode transistor device, one approach to provide an overall normally-off transistor device is a cascode configuration, where a low voltage normally-off device, such as a low voltage enhancement mode transistor, is placed in series with the high voltage normally-on device and the source of the low voltage normally-off transistor device is coupled to the gate of the high voltage normally-on transistor device. During normal operation, the normally-on device can be switched on- and off via the normally-off device. A driving voltage is applied to the gate of the normally-off device and the switching of the normally-on device may be indirectly controlled by switching the normally-off device.

A cascode arrangement may be used for III-V compound semiconductor devices, such as gallium nitride based High Electron Mobility Transistors (HEMTs). Due to the strong polar nature of some III-V based semiconductor devices, such as Group III nitride-based HEMTs, there may be strong polarization charges, which can cause the formation of inversion layers even in absence of any applied voltage. These III-V devices may be intrinsically normally-on, what means that a current can flow from drain to source terminals of the III-V devices even in absence of any control voltage applied to the gate electrode.

The low voltage enhancement mode transistor may be a silicon based Metal Oxide Semiconductor Field Effect Transistor (MOSFET).

In an embodiment, the semiconductor switching arrangement includes a normally-on semiconductor component having a first current electrode, a second current electrode and a first control electrode, a normally-off semiconductor component having a third current electrode, a fourth current electrode and a second control electrode, the third current electrode being coupled to the first control electrode and to a reference terminal and the fourth current electrode being coupled to the first current electrode and an actuation circuit having a fifth current electrode and a sixth current electrode. The sixth current electrode is coupled to a reference terminal and the fifth current electrode is coupled to the second control electrode to provide a control signal for switching the normally-off semiconductor component on or off. An output capacitance of the normally-on semiconductor component and an output capacitance of the normally-off semiconductor component fulfill the condition (COSS_Non*V_DD)/(COSS_Noff+CGS_Non)<Vbr_Noff−Vth_Non, wherein COSS_Non denotes the output capacitance of the normally-on semiconductor component, COSS_Noff denotes the output capacitance of the normally-off semiconductor component, CGS_Non denotes the capacitance between the first control electrode and the first current electrode, V_DD denotes the supply voltage, Vbr_Noff denotes the breakdown voltage of the normally-off semiconductor component and Vth_Non denotes the threshold voltage of the normally-on semiconductor component.

The normally-on semiconductor component may include a wide band gap semiconductor material such as silicon carbide and a group III nitride. The normally-off semiconductor component may include silicon. In some embodiments, the normally-on semiconductor component includes a High Electron Mobility Transistor and the normally-off semiconductor component includes a MOSFET.

In an embodiment, a method includes adjusting the leakage current of a low voltage enhancement mode transistor in a switching circuit comprising a high voltage depletion mode transistor operatively connected in a cascode arrangement to the low voltage enhancement mode transistor such that the leakage current of the low voltage enhancement mode transistor is higher than the leakage current of the high voltage depletion mode transistor within a predetermined temperature range. This method may be used to reduce the risk of, or avoid, static avalanche.

The adjustment of the leakage current of the low voltage enhancement mode transistor may include coupling one of the group consisting of a resistor and a diode in parallel with the low voltage enhancement mode transistor.

In some embodiments, the leakage current of the low voltage enhancement mode transistor is adjusted such that the leakage current of the low voltage enhancement mode transistor is at least 10 times greater than the leakage current of the high voltage depletion mode transistor within a predetermined temperature range.

The predetermined temperature range may be the operating temperature range of the switching circuit including the low voltage enhancement mode transistor and a high voltage depletion mode transistor and/or of one or both of the low voltage enhancement mode transistor and a high voltage depletion mode transistor.

The method may further include coupling a source electrode of the low voltage enhancement mode transistor to a gate electrode of the high voltage depletion mode transistor and coupling a drain electrode of the low voltage enhancement mode transistor to the source electrode of the high voltage depletion mode transistor, coupling an actuation circuit to a gate electrode of the low voltage enhancement mode transistor and the reference potential.

The method may include providing an output capacitance of the normally-on high voltage depletion mode transistor and an output capacitance of the low voltage enhancement mode transistor such that the condition (C_{OSS}_{_}_{Non}*V_DD)/(C_{OSS}_{_}_{Noff}+C_{GS}_{_}_{Non})<Vbr_{—Noff}−Vth_{—Non} is fulfilled, wherein C_{OSS}_{_}_{Non} denotes the output capacitance of the high voltage depletion mode transistor, C_{OSS}_{_}_{Noff} denotes the output capacitance of the low voltage enhancement mode transistor, C_{GS}_{_}_{Non} denotes the capacitance between the first control electrode and the first current electrode, V_DD denotes the supply voltage, Vbr_{—Noff} denotes the breakdown voltage of the low voltage enhancement mode transistor and Vth_{—Non} denotes the threshold voltage of the high voltage depletion mode transistor.

In an embodiment, a switching circuit includes a high voltage depletion mode transistor having a first leakage current operatively connected in a cascode arrangement to a low voltage enhancement mode transistor having a second leakage current, the second leakage current being larger than the first leakage current.

The high voltage depletion mode transistor may include a Group III nitride-based High Electron Mobility Transistor and the low voltage depletion mode transistor may include a MOSFET.

An output capacitance of the high voltage depletion mode transistor and an output capacitance of the low voltage enhancement mode transistor may be adjusted such that (C_{OSS}_{_}_{Non}*V_DD)/(C_{OSS}_{_}_{Noff}+C_{GS}_{_}_{Non})<Vbr_{—Noff}−Vth_{—Non}, wherein C_{OSS}_{_}_{Non} denotes the output capacitance of the high voltage depletion mode transistor, C_{OSS}_{_}_{Noff} denotes the output capacitance of the low voltage enhancement mode transistor, C_{GS}_{_}_{Non} denotes the capacitance between the gate and source of the high voltage depletion mode transistor, V_DD denotes the supply voltage, Vbr_{—Noff} denotes the breakdown voltage of the low voltage enhancement mode transistor and Vth_{—Non} denotes the threshold voltage of the high voltage depletion mode transistor.

In an embodiment, one of the group consisting of a resistor and a diode is coupled in parallel with the low voltage enhancement mode transistor.

FIG. 2 illustrates a schematic circuit diagram of a semiconductor switching arrangement 30 according to a second embodiment, which includes a normally-on semiconductor component 31 such as a depletion mode transistor, for example a depletion mode Group III nitride based HEMT, which has a source electrode 32, a drain electrode 33 and a gate electrode 34. The semiconductor switching arrangement 30 further includes a normally-off semiconductor component 35 such as an enhancement mode transistor, for example an enhancement mode silicon-based MOSFET coupled in series to the normally-on semiconductor component 31, which also has a source electrode 36, a drain electrode 37 and a gate electrode 38. The normally-off semiconductor component 35 is coupled in series to the normally-on semiconductor component 31 such that the drain electrode 37 of the normally-off semiconductor component 35 is connected to the source electrode 32 of the normally-on semiconductor component 31.

The normally-on semiconductor component 31 is operatively coupled in a cascode arrangement with the normally-off semiconductor component 35 so that the source electrode 36 of the normally-off semiconductor component 35 is connected to the gate electrode 34 of the normally-on semiconductor component 31

An actuation circuit 39 is electrically coupled to the gate electrode 38 of the normally-off semiconductor component to provide a control signal for switching the normally-off semiconductor component 35 on or off. In particular, the actuation circuit 39 has a first electrode 40 and a second electrode 41, the first electrode 40 being connected to the gate electrode 38 of the normally-off semiconductor component 35 and the second electrode 41 being coupled to a reference terminal. The source electrode 36 of the normally-off semiconductor component 35 and the gate electrode 34 of the normally-on semiconductor component 31 are coupled to the reference terminal.

Whilst the second electrode 41 and the source electrode 36 are illustrated in FIG. 2 as being coupled to ground, in other embodiments they may be coupled to a reference terminal and a reference potential which is higher than 0V.

The normally-on semiconductor component 31 illustrated in FIG. 2 may include a wide band gap semiconductor material such as silicon carbide (SiC) or a group III nitride gallium nitride (GaN) or aluminium gallium nitride (AlₓGa₍₁₋ₓ;N). Components including these semiconductor materials are distinguished from silicon components by a higher dielectric strength for a given switch-on resistance and by higher switching speeds.

The normally-off semiconductor component 35 may include a second semiconductor material, which is for example silicon. Normally-off semiconductor components including silicon can be produced with a high level of reliability and low absence of faults.

The normally-on semiconductor component 31 illustrated in FIG. 2 may be a Group III nitride-based HEMT 42 and the normally-off semiconductor component 35 may be a silicon-based MOSFET 43. A drain electrode 37 of the MOSFET 43 is connected to a source electrode 32 of the HEMT 42 and a source electrode 36 of the MOSFET 43 is connected to a gate electrode 34 of the HEMT 42. The HEMT is switched by a bias applied to a gate electrode 38 of the MOSFET 43. The use of a HEMT 42 as a normally-on component and of a MOSFET 43 as a normally-off component should merely be understood as an example, however. The normally-on semiconductor component 31 may be a JFET and the normally-off semiconductor component 35 used may be a bipolar transistor, an IGBT or a Group III-Nitride transistor.

The risk of static and/or dynamic avalanche occurring in a cascode solution may be reduced or avoided by adjusting the ratio of the leakage currents of the enhancement mode transistor and the depletion mode transistor. Alternatively, or in addition, dynamic avalanche may be reduced or avoided by adjusting capacitances, for example the output capacitance of the enhancement mode transistor and the depletion mode transistor.

For example, during switching, the maximum voltage between drain 37 and source electrode 36 of the normally-off MOSFET 43 can exceed the maximum rated voltage of the silicon device. Under this condition, the MOSFET 43 may enter avalanche breakdown causing a loss of controllability of the system and also most likely leading to a negative impact towards the reliability. For example, when the semiconductor switching arrangement is in its static off-state, the drain-to-source voltage of the MOSFET 43 can be charged by the leakage current of the normally-on semiconductor transistor 31 to a value being higher than its maximum rated voltage, driving the MOSFET 43 into stationary avalanche breakdown.

The ratio of the leakage currents of the two transistor devices coupled in a cascode arrangement may be controlled in order to avoid such a static avalanche breakdown by providing the normally-off semiconductor transistor 35 with a leakage current which is larger than the leakage current the normally-on semiconductor transistor 31.

The leakage current of the normally-off semiconductor transistor 35 may be 10 times larger than the leakage current of the normally-on semiconductor transistor 31, in order to have a safe margin and better avoid static avalanche.

Furthermore, the ratio of the leakage currents may be sustained for the whole operating temperature range of the semiconductor switching element. For example, for a 100 m Ohm design and an operating temperature of 25 degrees Celsius, the first leakage current may range between 10 nA and 100 nA (Ampere) and the second leakage current between 100 nA and 1 μ A. For an operating temperature of 150 degrees Celsius, the first leakage current may range between 1 μA and 10 μA and the second leakage current between 10 μA and 100 μA.

The leakage current of the normally-off semiconductor device may be adjusted by coupling a further leakage path in parallel to the semiconductor device. The semiconductor switching arrangement 30 may further include a resistor 44 coupled in parallel to the source electrode 36 and the drain electrode 37 of the normally-off semiconductor component 35. The resistor may be used to provide a further current leakage path and to assist in preventing the drain-to-source voltage build up in the MOSFET 43 from exceeding a value being higher than its maximum rated voltage, such preventing the MOSFET 43 of driving into stationary avalanche breakdown.

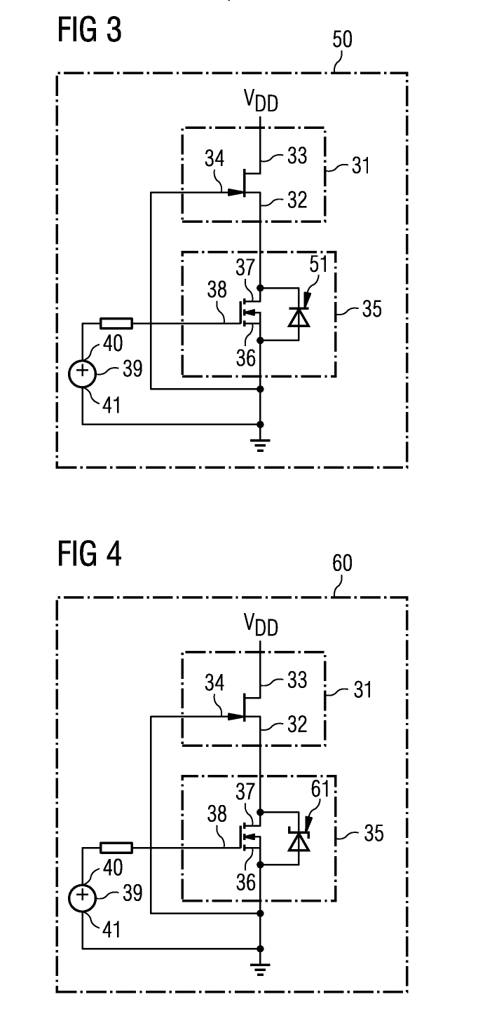

FIG. 3 illustrates a schematic circuit diagram of a semiconductor switching arrangement 50 according to a third embodiment. The semiconductor switching arrangement 50 includes a normally-on semiconductor component in the form of a high voltage depletion mode transistor 31 operatively coupled in a cascode configuration with a normally-off semiconductor component 35 in the form of a low voltage enhancement mode transistor and an actuation circuit 39 which is coupled to the gate electrode 38 of the low voltage enhancement mode transistor 35.

The semiconductor switching arrangement 50 includes a diode, such as a MOS-gated diode 51, coupled in parallel to the normally-off semiconductor component 35, in particular to the drain 37 and the source electrode 36 of the normally-off semiconductor component 35. The diode provides a further current leakage path in parallel with the low voltage enhancement mode transistor. The reduced potential barrier of the diode 51 may lead to a lower voltage drop in the forward direction and to a higher leakage current in the blocking direction. As used herein, a “MOS-gated diode” or “MGD” intends to describe a MOSFET structure with shorted gate electrode and source electrode, in example, a MGD is a two terminal field-effect structure.

Again, whilst the second electrode 41 of the actuation circuit 39 and the source electrode 36 are illustrated in FIG. 3 as being coupled to ground, in other embodiments they may be coupled to a reference terminal and a reference potential which is higher than 0V.

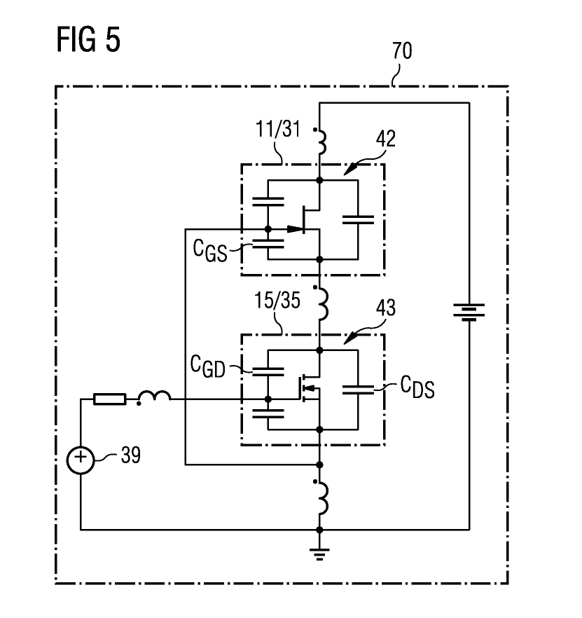

FIG. 4 illustrates a schematic circuit diagram of a semiconductor switching arrangement 60 according to a fourth embodiment. The semiconductor switching arrangement 60 includes a normally-on semiconductor component in the form of a high voltage depletion mode transistor 31 operatively coupled in a cascode configuration with a normally-off semiconductor component in the form of a low voltage enhancement mode transistor 35 and an actuation circuit 39 which is coupled to the gate electrode 38 of the low voltage enhancement mode transistor 35. Whilst the second electrode 41 and the source electrode 36 are illustrated in FIG. 4 as being coupled to ground, the semiconductor switching arrangement is not limited to this arrangement and in other embodiments the second electrode 41 and the source electrode 36 may be coupled to a reference potential which is higher than 0V.

The semiconductor switching arrangement 60 includes a Schottky diode 61 coupled in parallel to the low voltage enhancement mode transistor 35 which provides a further current leakage path. The Schottky diode is coupled between the drain 37 and the source electrode 36 of the high voltage depletion mode transistor 31, in order to achieve a low body diode knee voltage linked to an increase and, therefore, to control the second leakage current in order to prevent the drain-to source voltage build up in the MOSFET from exceeding a value being higher than its maximum rated voltage.

Schottky diodes may be used as body diodes for low voltage devices as Schottky diodes generally have lower knee voltages compared to semiconductor diodes. Other solutions to achieve low threshold voltage include the implementation, or an additional quasi-body diode buried in the bulk below the device. The quasi-body diode may include SiGe or SiGeC.

FIG. 5 illustrates a schematic circuit diagram of a semiconductor switching arrangement 70 according to a fifth embodiment. The semiconductor switching arrangement 70 includes a normally-on semiconductor component in the form of a high voltage depletion mode transistor 31 operatively coupled in a cascode configuration with a normally-off semiconductor component in the form of a low voltage enhancement mode transistor 35 and an actuation circuit 39 which is coupled to the gate electrode 38 of the low voltage enhancement mode transistor 35. Whilst the second electrode 41 and the source electrode 36 are illustrated in FIG. 5 as being coupled to ground, in other embodiments the second electrode 41 and the source electrode 36 are coupled to a reference potential which is higher than 0V.

In particular, FIG. 5 illustrates a simplified schematic circuit diagram of a semiconductor switching arrangement 70.

The normally-on semiconductor component 31 may be a Group III nitride-based HEMT 42, the normally-off semiconductor component 35 may be a silicon-based MOSFET 43. The operation of the semiconductor switching arrangement 70 is similar to that described above. In particular, a driving voltage is applied to the gate electrode 38 of the MOSFET 43 to switch the MOSFET 43 on and off and thereby indirectly switch the GaN HEMT 42 on or off.

When the semiconductor switching arrangement 70 is switching from the on-state to the off-state, a drain-to-source voltage of the MOSFET 43 may rise up to a value higher than its maximum rated voltage, and the MOSFET 43 may enter dynamic avalanche breakdown. The risk of dynamic avalanche occurring may be reduced or avoided by an adequate selection of the device capacitances.

The main device capacitances of both the normally-on semiconductor component 31 as well as the normally-off semiconductor component 35 are indicated in FIG. 5.

During switching of the semiconductor switching arrangement 70, the drain-to-source voltage of the MOSFET 43 may be determined according three device parameters, in particular the gate-to-source capacitance C_{GS}_{_}_{GaN} of the GaN HEMT 42, the gate-to-drain capacitance C_{GD}_{_}_{Si} of the MOSFET 43 and the drain-to-source capacitance C_{DS}_{_}_{Si} of the MOSFET 43. The sum of the gate-to-drain capacitance C_{GD}_{_}_{Si} of the MOSFET 43 and the drain-to-source capacitance C_{DS}_{_}_{Si} of the MOSFET 43 is the output capacitance, C_{OSS}_{_}_{Si} of the MOSFET 43. In particular, the drain-to-source voltage of the MOSFET 43 may be reduced by increasing the values of the gate-to-drain capacitance C_{GD}_{_}_{Si} and the drain-to-source capacitance C_{DS}_{_}_{Si} of the MOSFET 43 in comparison to the gate-to-source capacitance C_{GS}_{_}_{GaN} of the GaN HEMT 42.

The output capacitance C_{OSS} of the GaN HEMT 42 may affect the overall performance of the semiconductor switching arrangement 70 and may be minimized in order to reduce the maximum drain-to-source voltage of the MOSFET 43.

The device parameters of the semiconductor switching arrangement may fulfill the condition:

V_BR_{—Si}=(C_{OSS}_{_}_{GaN}*V_DD+(C_{GD}_{_}_{Si}+C_{DS}_{_}_{Si}+C_{GS}_{_}_{GaN})*V_TH_{—GaN})/(C_{GD}_{_}_{Si} +C_{DS}_{_}_{Si}+C_{GS}_{_}_{GaN}),

wherein V_BR_{—Si} denotes the maximum rated voltage of the MOSFET, V_DD denotes the supply voltage and V_TH_{—GaN} denotes the GaN HEMT threshold voltage.

More simplified, this condition can be expressed as follows:

(C_{OSS}_{_}_{GaN}*V_DD)/(C_{OSS}_{_}_{Si}+C_{GS}_{_}_{GaN})<V_BR_{—Si}−V_TH_{—GaN},

wherein C_{OSS}_{_}_{Si} denotes the output capacitance of the silicon MOSFET 43 and V_BR_{—Si} denotes the breakdown voltage of silicon MOSFET 43.

Furthermore, in order to fulfill this condition, the device parameters may be chosen according to the following conditions, for example:

C_{ISS}_{_}_{GaN}/C_{OSS}_{_}_{GaN}≧10

C_{GD}_{_}_{Si}/C_{OSS}≧5.5

C_{DS}_{_}_{Si}/C_{OSS}≧45

C_{GD}_{_}_{Si}/C_{GS}_{_}_{Si}>1,

wherein C_{DSS}_{_}_{GaN} denotes the input capacitance of the GaN HEMT 42.

For example, for a 100 m Ohm design and a supply voltage V_DD of 400 Volt, the output capacitance C_{OSS}_{_}_{GaN} of the GaN HEMT 42 may range between 20 pF and 50 pF, the gate-to source capacitance C_{GS}_{_}_{GaN} of the GaN HEMT 42 may be larger than 200 p farad, the gate-to-drain capacitance C_{GD}_{_}_{Si} of the MOSFET 43 may be equal or larger than 110 p farad and the drain-to-source capacitance C_{DS}_{_}_{Si} of the MOSFET 43 may be equal or larger than 900 p farad, with the GaN HEMT threshold voltage V_TH being −7 volt.

The gate-to-source capacitance C_{GS}_{_}_{Si} of the MOSFET 43 may be chosen such that it is high enough to keep the capacitive spurious turn-on of the MOSFET 43 at a level which would not be detrimental for the overall performance and such that it is low enough so that the overall gate charge is not exceeding a certain limit set by the particular application circuit.

If the absolute value of the GaN threshold voltage V_TH_{—GaN} increases, stress on the MOSFET 43 may also increase and may further increase the risk of dynamic avalanche and instabilities. As a consequence V_TH_{—GaN} may lie in a range in the order of [−9V, −3V] may be selected. A lower absolute value of the GaN threshold voltage V_TH_{—GaN} may for example be achieved with a procedure such as, for example, a selected barrier recess below the gate region. The switching arrangement 70 is robust against oscillations and package parasitics.

A combination of the adjustment of the ratio of the leakage current of the depletion mode transistor and the leakage current of the enhancement mode transistor of the cascode arrangement and the selection of the capacitances may also be used to reduce the risk of, or to avoid, both static and dynamic avalanche.

Spatially relative terms such as “under”, “below”, “lower”, “over”, “upper” and the like are used for ease of description to explain the placement of one element relative to a second element. These terms are intended to encompass different orientations of the device in addition to different orientations than those depicted in the figures.

Further, terms such as “first”, “second”, and the like, are also used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

It is to be understood that the features of the various embodiments described herein may be combined with each other, unless specifically noted otherwise.

Although specific embodiments have been illustrated and de-scribed herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A switching circuit, comprising:
a high voltage depletion mode transistor having a first leakage current and operatively connected in a cascode arrangement to a low voltage enhancement mode transistor having a second leakage current, the second leakage current being larger than the first leakage current.

2. The switching circuit according to claim 1, wherein the high voltage depletion mode transistor is a Group III nitride-based High Electron Mobility Transistor (HEMT) and the low voltage enhancement mode transistor is a MOSFET.

3. The switching circuit according to claim 1, wherein an output capacitance of the high voltage depletion mode transistor and an output capacitance of the low voltage enhancement mode transistor fulfill the condition (C_{OSS}_{_}_{Non}*V_DD)/(C_{OSS}_{_}_{Noff}+C_{GS}_{_}_{Non})<Vbr_{—Noff}−Vth _{_}_{Non}, wherein C_{OSS}_{_}_{Non} denotes the output capacitance of the high voltage depletion mode transistor, C_{OSS}_{_}_{Noff} denotes the output capacitance of the low voltage enhancement mode transistor, C_{GS}_{_}_{Non} denotes a capacitance between a gate and source of the high voltage depletion mode transistor, V_DD denotes a supply voltage of the switching circuit, Vbr_{—Noff} denotes a breakdown voltage of the low voltage enhancement mode transistor and Vth_{—Non} denotes a threshold voltage of the high voltage depletion mode transistor.

4. The switching circuit according to claim 1, wherein one of a resistor and a diode is coupled in parallel with the low voltage enhancement mode transistor.

5. A method, comprising:
adjusting a leakage current of a low voltage enhancement mode transistor in a switching circuit comprising a high voltage depletion mode transistor operatively connected in a cascode arrangement to the low voltage enhancement mode transistor such that the leakage current of the low voltage enhancement mode transistor is higher than a leakage current of the high voltage depletion mode transistor within a predetermined temperature range.

6. The method according to claim 5, wherein adjusting the leakage current of the low voltage enhancement mode transistor comprises coupling one of a resistor and a diode in parallel with the low voltage enhancement mode transistor.

7. The method according to claim 5, wherein the leakage current of the low voltage enhancement mode transistor is adjusted such that the leakage current of the low voltage enhancement mode transistor is at least 10 times greater than the leakage current of the high voltage depletion mode transistor within a predetermined temperature range.

8. The method according to claim 5, further comprising:
coupling a source electrode of the low voltage enhancement mode transistor to a gate electrode of the high voltage depletion mode transistor;
coupling a drain electrode of the low voltage enhancement mode transistor to a source electrode of the high voltage depletion mode transistor; and
coupling an actuation circuit to a gate electrode of the low voltage enhancement mode transistor and a reference terminal.

9. The method according to claim 5, further comprising providing an output capacitance of the high voltage depletion mode transistor and an output capacitance of the low voltage enhancement mode transistor such that the condition (C_{OSS}_{_}_{Non}*V_DD)/(C_{OSS}_{_}_{Noff}+C_{GS}_{_}_{Non})<Vbr_{—Noff}−Vth_{—Non} is fulfilled, wherein C_{OSS}_{_}_{Non} denotes the output capacitance of the high voltage depletion mode transistor, C_{OSS}_{_}_{Noff} denotes the output capacitance of the low voltage enhancement mode transistor, C_{Gs}_{_}_{Non} denotes a capacitance between the first control electrode and the first current electrode, V_DD denotes a supply voltage of the switching circuit, Vbr_{—Noff} denotes a breakdown voltage of the low voltage enhancement mode transistor and Vth_{—Non} denotes a threshold voltage of the high voltage depletion mode transistor.

10. A semiconductor switching arrangement, comprising:
a normally-on semiconductor component having a first current electrode, a second current electrode and a first control electrode, the normally-on semiconductor element providing a first leakage current;
a normally-off semiconductor component having a third current electrode, a fourth current electrode and a second control electrode, the third current electrode being coupled to the first control electrode and to a reference terminal and the fourth current electrode being coupled to the first current electrode, the normally-off semiconductor component providing a second leakage current; and
an actuation circuit having a fifth current electrode and a sixth current electrode, the sixth current electrode being coupled to the reference terminal and the fifth current electrode being coupled to the second control electrode to provide a control signal for switching the normally-off semiconductor component on or off,
wherein the second leakage current is larger than the first leakage current.

11. The semiconductor switching arrangement according to claim 10, wherein the normally-on semiconductor component comprises silicon carbide or a Group III nitride.

12. The semiconductor switching arrangement according to claim 10, wherein the normally-off semiconductor component comprises silicon.

13. The semiconductor switching arrangement according to claim 10, wherein the normally-on semiconductor component is a High Electron Mobility Transistor (HEMT) and the normally-off semiconductor component comprises a MOSFET.

14. The semiconductor switching arrangement according to claim 10, wherein the second leakage current is ten times larger than the first leakage current.

15. The semiconductor switching arrangement according to claim 10, further comprising a further leakage current path coupled in parallel with the third current electrode and the fourth current electrode, the further leakage current path comprising a resistor, a MOS-gated diode or a Schottky diode.

16. The semiconductor switching arrangement according to claim 10, wherein an output capacitance of the normally-on semiconductor component and an output capacitance of the normally-off semiconductor component fulfill the condition (C_{OSS}_{_}_{Non}*V_DD)/(C_{OSS}_{_}_{Noff}+C_{GS}_{_}_{Non})<Vbr_{—Noff}−Vth_{—Non}, wherein C_{OSS}_{_}_{Non} denotes the output capacitance of the normally-on semiconductor component, C_{OSS}_{_}_{Noff} denotes the output capacitance of the normally-off semiconductor component, C_{GS}_{_}_{Non} denotes a capacitance between the first control electrode and the first current electrode, V_DD denotes a supply voltage of the semiconductor switching arrangement, Vbr_{—Noff} denotes a breakdown voltage of the normally-off semiconductor component and Vth_{—Non} denotes a threshold voltage of the normally-on semiconductor component.

17. A semiconductor switching arrangement, comprising:
a normally-on semiconductor component having a first current electrode, a second current electrode and a first control electrode;
a normally-off semiconductor component having a third current electrode, a fourth current electrode and a second control electrode, the third current electrode being coupled to the first control electrode and to a reference terminal and the fourth current electrode being coupled to the first current electrode; and
an actuation circuit having a fifth current electrode and a sixth current electrode, the sixth current electrode being coupled to a reference terminal and the fifth current electrode being coupled to the second control electrode to provide a control signal for switching the normally-off semiconductor component on or off,
wherein an output capacitance of the normally-on semiconductor component and an output capacitance of the normally-off semiconductor component fulfill the condition (COSS_Non*V_DD)/(COSS_Noff+CGS_Non)<Vbr_Noff−Vth_Non, wherein COSS Non denotes the output capacitance of the normally-on semiconductor component, COSS_Noff denotes the output capacitance of the normally-off semiconductor component, CGS_Non denotes a capacitance between the first control electrode and the first current electrode, V_DD denotes a supply voltage of the semiconductor switching arrangement, Vbr_Noff denotes a breakdown voltage of the normally-off semiconductor component and Vth_Non denotes a threshold voltage of the normally-on semiconductor component.

18. The semiconductor switching arrangement according to claim 17, wherein the normally-on semiconductor component comprises silicon carbide or a group III nitride.

19. The semiconductor switching arrangement according to claim 17, wherein the normally-off semiconductor component comprises silicon.

20. The semiconductor switching arrangement according to claim 17, wherein the normally-on semiconductor component is a High Electron Mobility Transistor (HEMT) and the normally-off semiconductor component comprises a MOSFET.
